(19) United States
(12) Patent Application Publication
(10) Pub. No.: US 2007/0123042 A1
(43) Pub. Date: May 31, 2007

(54) METHODS TO FORM HETEROGENEOUS SILICIDES/GERMANIDES IN CMOS TECHNOLOGY

(75) Inventors: Kern Rim, Yorktown Heights, NY (US); John J. Ellis-Monaghan, Grand Isle, VT (US); Brian J. Greene, Yorktown Heights, NY (US); William K. Henson, Peekskill, NY (US); Robert J. Purtell, Mohegan Lake, NY (US); Clement H. Wann, Carmel, NY (US); Horatio S. Wildman, Wappingers Falls, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/164,511

(22) Filed: Nov. 28, 2005

(51) Int. Cl. H01L 21/44

(52) U.S. Cl. 438/683

(57) ABSTRACT

Methods of fabricating a semiconductor structure including heterogeneous suicides or germanides located in different regions of a semiconductor structure are provided. The heterogeneous suicides or germanides are formed onto a semiconductor layer, a conductive layer or both. In accordance with the present invention, the inventive methods utilize a combination of sequential deposition of different metals and patterning to form different suicides or germanides in different regions of a semiconductor chip. The method includes providing a Si-containing or Ge layer having at least a first region and a second region; forming a first silicide or germanide on one of the first or second regions; and forming a second silicide or germanide that is compositionally different from the first silicide or germanide on the other region not including the first silicide or germanide, wherein the steps of forming the first and second suicides or germanides are performed sequentially or in a single step.

### FIELD OF THE INVENTION

The present invention relates to semiconductor manufacturing and more particularly to methods of fabricating a semiconductor structure including heterogeneous suicides or germanides located in different regions of a semiconductor structure.

### BACKGROUND OF THE INVENTION

In order to fabricate integrated circuits (ICs) of increased performance than is currently feasible, device contacts must be developed which reduce the electrical contact resistance to the IC's Si-containing body or integrated electronic device formed therein. A contact is the electrical connection, typically at a Si-containing or germanium, Ge, surface, between the devices in the Si-containing or Ge material and the metal layers that serve as interconnects. Interconnects serve as the metal wiring that carry electrical signals throughout the chip.

Silicide contacts, and to a lesser extent germanide contacts, are of specific importance to ICs including complementary metal oxide semiconductor (CMOS) devices because of the need to reduce the electrical resistance of the contacts at the source/drain and gate regions. Silicides are metal compounds that are generally thermal stable and provide for low resistivity at the Si/metal interface. Germanides are metal compounds that are also generally thermal stable and provide for low resistivity at the Ge/metal interface. Silicides/germanides generally have lower barrier heights thereby improving the contact resistance. Reducing contact resistance from silicide to Si diffusion or germanide to Ge diffusion improves device speed and therefore increases the device performance.

In today's generation of CMOS devices, CoSi₂ (i.e., cobalt disilicide) and NiSi (i.e., nickel monosilicide) are commonly used for salicide formation. The salicide process (which represents a self-aligned silicidation process) typically includes depositing a metal that is capable of reacting with a Si-containing material on a surface of the Si-containing material. First annealing at a temperature that causes interaction between the metal and the Si-containing material and formation of a metal silicide. Removing any remaining unreacted metal from the surface of the Si-containing material. An optional second anneal can be performed to transform the silicide film to a different, second phase and further lower the resistance of the silicide. Germanides can also be formed utilizing the aforementioned salicide process when a metal or metal alloy is formed on a Ge surface.

In principle, decreasing Schottky barrier height of the silicide (or germanide) to either the n+ or p+ diffusion of an nFET and pFET, respectively, increases the barrier height for the other diffusion type. Thus, choosing a silicide (or germanide) material with lower contact resistance to p+ diffusion, such as PtSi (or PtGe), for example, will increase the contact resistance to the n+ diffusion. As such, methods for providing a semiconductor structure containing a heterogeneous silicide (or germanide) on nFETs and pFETS to allow independent optimization of silicide (or germanide) contact resistance are needed.

### SUMMARY OF THE INVENTION

The present invention provides methods of fabricating a semiconductor structure including heterogeneous suicides or germanides located in different regions of a semiconductor structure. The heterogeneous suicides or germanides are formed within a semiconductor layer, a conductive layer or both. The semiconductor layer including the suicides and germanides may include diffusion regions. In accordance with the present invention, the inventive methods utilize a combination of sequential deposition of different metals and patterning to form different suicides or germanides in different regions of a semiconductor chip. A self-aligned silicidation process is used in providing the suicides or germanides. The present invention contemplates a single silicide or germanide formation process or a dual silicide or germanide formation process.

In broad terms, the method of the present invention comprises:
providing a Si-containing or Ge layer having at least a first region and a second region;
forming a first silicide or germanide on one of said first or second regions; and
forming a second silicide or germanide that is compositionally different from said first silicide or germanide on said other region not including said first silicide or germanide,
   wherein said steps of forming said first and second suicides or germanides are performed sequentially or in a single step.

In one embodiment of the present invention, the first and second suicides or germanides are formed in a single step. In this single formation scheme, a patterned first metal is formed on the Si-containing or Ge layer in one of the regions and thereafter a second metal is formed such that a portion thereof is in contact with said Si-containing or Ge layer in the other region not including the patterned first metal. The structure is then subjected to a single silicidation process which converts the first and second metals into first and second suicides and germanides, respectively. In accordance with the present invention, the first and second metals and hence the first and second suicides and germanides are compositionally different from each other.

Variations of the single formation scheme of the present invention are also contemplated. In one variation, some of the second metal diffuses into the patterned first metal forming a silicide or germanide that includes both said first and second metals. In yet another variation of the single formation scheme, the first metal is unpatterned and a patterned hard mask is formed over one of the regions, a second metal is then formed over both regions and a single silicidation process is performed. This variation can be used, for example, in forming a first region including PtSi and a second region including NiPtSi. In such an embodiment, the PtSi would be located in the region containing a p+ diffusion, while the NiPtSi would be located in the region containing an n+ diffusion.

In another embodiment of the present invention, a dual formation scheme is provided. In the dual formation scheme, a patterned hard mask is first provided over one of the two regions, an unpatterned first metal is formed and then subjected to a first silicidation process. After silicidation, any unreacted first metal and the patterned hard mask is removed from the structure and a second metal is formed. A second silicidation process is then performed.

The above methods provide semiconductor structures including heterogeneous suicides or germanides in different regions thereof which allow independent optimization of silicide and germanide contact resistance.

### BRIEF DESCRIPTION OF THE DRAWINGS

FIGS. 1A-1B are pictorial representations (through cross sectional views) depicting one embodiment of the present invention.

FIGS. 2A-2D are pictorial representations (through cross sectional views) depicting another embodiment of the present invention.

FIGS. 3A-3B are pictorial representations (through cross sectional views) depicting a first variation to the embodiment depicted in FIGS. 1A-1B.

FIGS. 4A-4G are pictorial representations (through cross sectional views) depicting a preferred embodiment of the present invention.

### DETAILED DESCRIPTION OF THE INVENTION

The present invention, which provides methods to form a semiconductor structure having heterogeneous silicides/germanides in different regions thereof, will now be described in greater detail by referring to the following discussion and drawings that accompany the present application. It is noted that the drawings of the present application are provided for illustrative purposes and, as such, they are not drawn to scale. Moreover, in the various embodiments depicted in the drawings, like and corresponding elements are referred to by like reference numerals.

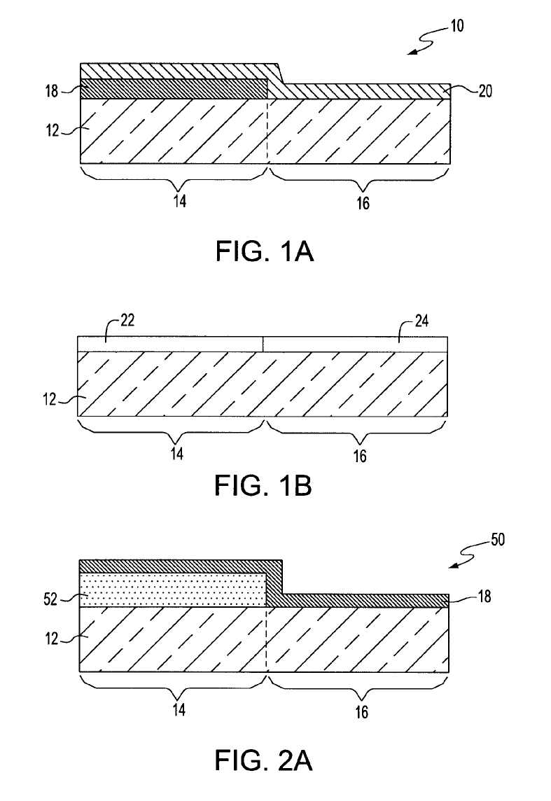

Reference is first made to FIGS. 1A-1B which illustrate an embodiment of the present invention in which a single formation scheme is employed in forming the heterogeneous silicides/germanides. FIG. 1A shows an initial structure 10 that includes a Si-containing or Ge layer 12 that has a first region 14 and a second region 16. As specifically shown, the initial structure 10 includes a patterned first metal 18 located on a surface of layer 12 within the first region 14 and a second metal 20 located within both regions 14 and 16. The second metal 20 is located atop the patterned first metal 18 in the first region 14 and is located on a surface of layer 12 in the second region 16. Although this embodiment is specifically shown, the present invention also contemplates when the patterned first metal 18 is located within the second region 16 and the second metal 20 is located within both regions 14 and 16.

The Si-containing or Ge layer 12 may be coplanar as shown in FIG. 1A, or non-coplanar. When a non-coplanar layer is used, the height of layer 12 in one of the regions is different from the height of layer 12 in the other region. Layer 12 may be a semiconducting material, a conductive material or both. Layer 12 may be doped (i.e., have diffusion regions therein), undoped or it may have regions that are doped and regions that are undoped. Layer 12 can be strained, unstrained or contain regions of both strain and unstrain therein. Layer 12 can be of a single crystal orientation or layer 12 can have different surface crystal orientations. When different surface crystal orientations are employed, one of regions 14 and 16 may have a first crystal orientation and the other of regions 14 or 16 has a second crystal orientation that differs from the first.

The term “Si-containing” is used herein to denote a material that includes silicon, Si. Examples of such Si-containing materials include, but are not limited to: Si, SiGe, SiGeC, SiC, silicon-on-insulators, and silicon germanium-on-insulators. Layered Si-containing materials are also contemplated herein.

The patterned first metal 18 is formed by applying a blanket layer of first metal on to the upper surface of layer 12 and then patterning that blanket first metal layer 18 by lithography and etching. The blanket layer of first metal 18 may be applied to the upper surface of layer 12 utilizing a conventional deposition process such as, for example, chemical vapor deposition (CVD), plasma enhanced chemical vapor deposition (PECVD), evaporation, sputtering, plating, chemical solution deposition, metalorgano deposition and other like deposition process. The lithographic step includes first applying a photoresist (not shown) to the as deposited layer of first metal, exposing the photoresist to a pattern of radiation and developing the photoresist utilizing a conventional resist developer. The etching step can include a dry etching process such as, for example, reactive-ion etching, plasma etching, ion beam etching or laser ablation. The etching process can also include a chemical wet etching process in which a chemical etchant is used to remove the exposed portions of the first metal layer 18. An example of a chemical etchant that can be used in the present invention in this step includes aqua regia and sulfuric acid with hydrogen peroxide.

The first metal 18 comprises a metal or metal alloy that is capable of reacting with a Si-containing material or Ge in forming a silicide or germanide, respectively. The first metal 18 can be composed of Ti, Ta, W, Co, Ni, Pt, Pd or alloys thereof. Typically, the first metal includes one of Ti, Co, Ni, Pt or alloys thereof, with Ni or Pt alloys being particularly preferred in one embodiment of the present invention.

The first metal 18 can also include one or more alloying additives including, for example, C, Al, Ti, V, Cr, Mn, Fe, Co, Ni, Cu, Ge, Zr, Nb, Mo, Ru, Rh, Ag, In, Sn, Hf, Ta, W, Re, Ir or Pt, with the proviso that the one of more alloying additives is not the same as the metal used in forming the silicide or germanide. When present, the one or more alloying additives is present in an amount from about 0.1 to about 50 atomic percent. The alloying additive can be added in-situ during the deposition of the first metal 18, or it can be introduced after the first metal 18 is deposited by ion implantation, plasma immersion or gas phase doping.

The thickness of the as deposited first metal 18 may vary depending upon the overall thickness of layer 12. Typically, the thickness of the first metal 18 is from about 2 to about 20 nm, with a thickness from about 5 to about 10 nm being more typical.

After patterning of the blanket layer of first metal 18, the patterned photoresist is removed from the structure utilizing a conventional stripping process and thereafter the patterned first metal 18 is cleaned utilizing a conventional cleaning process that removes oxide and/or residual resist from the patterned first metal.

A blanket layer of second metal 20 (which is compositionally different from the first metal 18) is then formed on the initial structure 10 including atop the patterned first metal 18 and the exposed surface of the Si-containing or Ge layer 12. As such, the blanket layer of second metal 20 is present in both the first region 14 and the second region 16. The second metal 20 is formed utilizing the same or different deposition process as that used in forming the first metal. As stated above, the second metal 20 is compositionally different from that of the first metal 18. For example, when the first metal 18 is Pt, the second metal 20 can be PtNi.

The thickness of the second metal 20 formed at this point of the present invention is within the range mentioned above for the first metal 18.

In some embodiments (not shown), an oxygen diffusion barrier such as TiN or TaN is formed atop the second metal 20 at this point of the present invention. The optional oxygen diffusion barrier, which is formed by a conventional deposition process, typically has a thickness from about 5 to about 50 nm.

After forming the initial structure 10 shown in FIG. 1A, the initial structure 10 is annealed utilizing a single self-aligned silicidation process which forms a first silicide or germanide 22 in, for example, first region 14 and a second silicide or germanide 24, in for example, second region 16, wherein said first and second silicide or germanide are compositionally different from each other. The resultant structure after performing the single step self-aligned silicidation process is shown, for example, in FIG. 1B.

The single self-aligned silicidation process includes a first anneal, removing any unreacted first and second metal from the structure together with the optional oxygen diffusion barrier, and optionally a second anneal. The first anneal is typically performed at lower temperatures than the second annealing step. Typically, the first anneal, which may or may not form a silicide or germanide in its lowest resistance phase, is performed at a temperature of about 300° C. or greater, with a temperature from about 350° to about 650° C. being even more typical. The first anneal may be performed using a continuous heating regime or various ramp and soak cycles can be used. The first anneal is typically carried out in a gas atmosphere such as, for example, He, Ar, N₂ or a forming gas anneal. The annealing time may vary depending on the metals or metal alloys used in forming the suicides or germanides. Typically, the annealing is performed for a time period from about 5 seconds to about 2 hours. The annealing process may be a furnace anneal, a rapid thermal anneal, a laser anneal, a spike anneal or a microwave anneal.

A selective wet etch process(es) can be used to remove any unreacted first and second metal as well as the optional oxygen diffusion barrier from the structure.

The second annealing step, if performed, is typically carried out at a temperature of about 550° C. or greater, with a temperature from about 600° to about 800° C. being more typical. The second anneal may be performed in the same or different gas atmosphere as the first anneal.

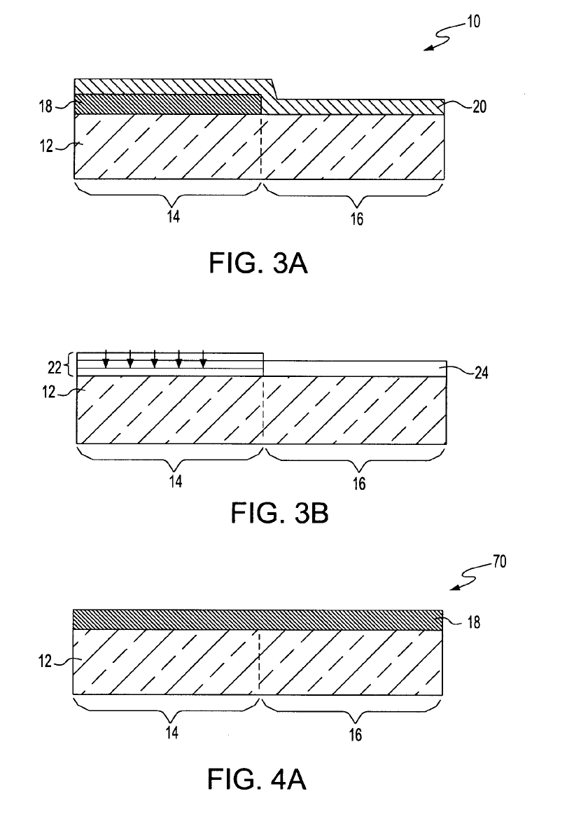

In this particular case, no diffusion between the first and second metal layers occurs since the first metal acts as the diffusion barrier. In some embodiments, such as nickel and cobalt, diffusion may occur (see for example FIGS. 3A-3B).

It is again emphasized that the second anneal is optional and need not be performed if the silicide or germanide formed after the first anneal is in its lowest resistance phase. For example, when Co is used, a two-step anneal is needed to form CoSi₂. When Ni or Pt is used, a single anneal is used in forming NiSi or PtSi.

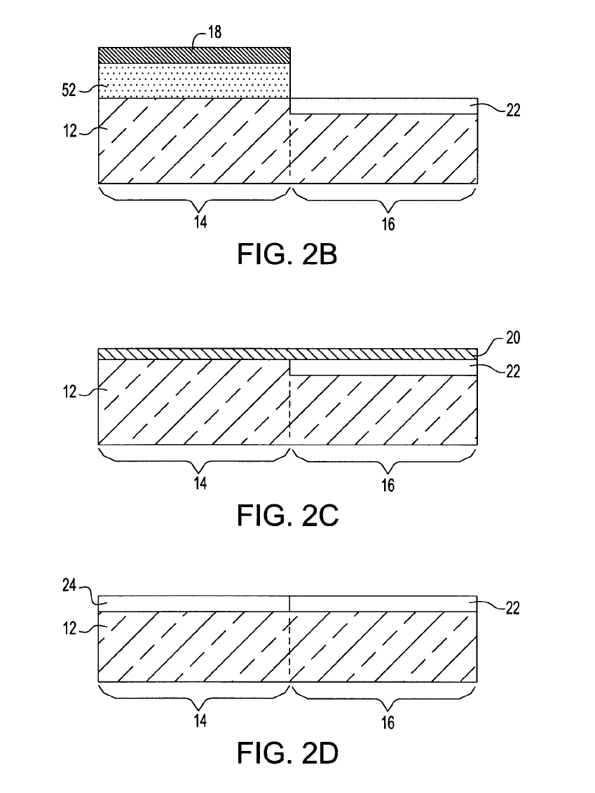

FIGS. 2A-2D depict another embodiment of the present invention in which a dual formation scheme is employed. In these drawings, like elements and/or components as employed above in FIGS. 1A and 1B are referred to by like reference numerals.

In the dual formation scheme illustrated in FIGS. 2A-2D, a first silicide or germanide is formed in one of the regions utilizing a first self-aligned silicidation process, and a second silicide or germanide that is compositionally different from the first silicide or germanide is then formed in the remaining region utilizing a second self-aligned silicidation process.

FIG. 2A illustrates an initial structure 50 utilized in this embodiment of the present invention. As shown, the initial structure 50 includes a patterned hard mask 52 located on a surface of a Si-containing or Ge layer 12 in the first region 14. Although the patterned hard mask 52 is shown in the first region 14, the present invention also contemplates the case when the patterned hard mask 52 is located in the second region 16. The initial structure 50 also includes a first metal layer 18 in both the first region 14 and the second region 16. As shown, the first metal layer 18 is located atop the patterned hard mask 52 in the first region 14 and on a surface of layer 12 in the second region 16.

The patterned hard mask 52 is formed by first forming a blanket layer of hard mask material (oxide, nitride or oxynitride) on layer 12 in both regions 14 and 16. The blanket hard mask is formed by a conventional deposition process such as, for example, CVD, PECVD, evaporation, sputtering, chemical solution deposition and other like deposition processes. In some embodiments, the blanket hard mask can be formed by a thermal technique such as, for example, oxidation or nitridation. The thickness of the as deposited blanket hard mask may vary depending on the type of hard mask material employed as well as the technique used in forming the same. Typically, the as deposited hard mask has a thickness from about 5 to about 50 nm.

After depositing the blanket layer of hard mask material, lithography and etching, as described above, are used in patterning the hard mask material.

The first metal layer 18 is formed utilizing a deposition process as described above in the first embodiment for the patterned first metal 18 and it has a thickness that is also within the range described above.

After providing the structure shown in FIG. 2A, a first self-aligned silicidation process can be performed providing the structure shown, for example, in FIG. 2B. In this structure, a first silicide or germanide 22 is formed from the first self-aligned silicidation process. The first silicidation process includes a first anneal, removing the unreacted first metal layer and optional oxygen diffusion barrier that can be formed prior to silicidation, and an optional second anneal. The first and optional second anneal are performed utilizing the conditions mentioned above in forming the structure shown in FIG. 1B.

After the first self-aligned silicidation process, the patterned hard mask 52 is removed from the structure utilizing a conventional stripping process that is selective in removing hard mask material and thereafter a second metal layer 20 is formed across the entire structure including the first silicide or germanide 22. The second metal layer 20 is formed as described above in the first embodiment of the present invention. The resultant structure including the second metal layer 20 is shown, for example, in FIG. 2C.

After providing the second metal layer 20 to the structure including the first silicide or germanide 22, a second self-aligned silicidation process is performed which forms a second silicide or germanide 24 that is compositionally different from the first silicide or germanide. The second self-aligned silicidation process includes the same or different conditions as the first self-aligned silicidation process used in forming the structure shown in FIG. 2B. The resultant structure that is formed after the second self-aligned silicidation process has been performed is shown, for example, in FIG. 2D.

FIGS. 3A-3B show a first variation to the embodiment depicted in FIGS. 1A-1B. That is, these drawings of the present invention show a variation to the single formation scheme shown in FIGS. 1A-1B. In these drawings, like elements and/or components as employed above in FIGS. 1A and 1B are referred to by like reference numerals.

FIG. 3A, like FIG. 1A, shows the initial structure 10. The initial structure 10 includes a Si-containing or Ge layer 12 that has a first region 14 and a second region 16. As specifically shown, the initial structure 10 includes a patterned first metal 18 located on a surface of layer 12 within the first region 14 and a second metal 20 located within both regions 14 and 16. The second metal 20 is located atop the first metal 18 in the first region 14 and is located on a surface of layer 12 in the second region 16. Although this embodiment is specifically shown, the present invention also contemplates when the patterned first metal 18 is located within the second region 16 and the second metal 20 is located within both regions 14 and 16.

The conditions and techniques described above in fabricating the structure shown in FIG. 1A are applicable here in providing the structure shown in FIG. 3A. FIG. 3B shows the structure during the single self-aligned silicidation process. As shown, a single simultaneous self-aligned silicidation process is used to form the first and second silicide or germanides 22 and 24, respectively. In this variation, some of the second metal from layer 20 in the first region 14 diffuses into the first metal layer 18 as shown by the solid arrows, and the resulting silicide or germanide 22 formed in the first region 14 is an alloy composed of the first and second metals or metal alloys. The single self-aligned silicidation process is performed as described above in the first embodiment of the present invention.

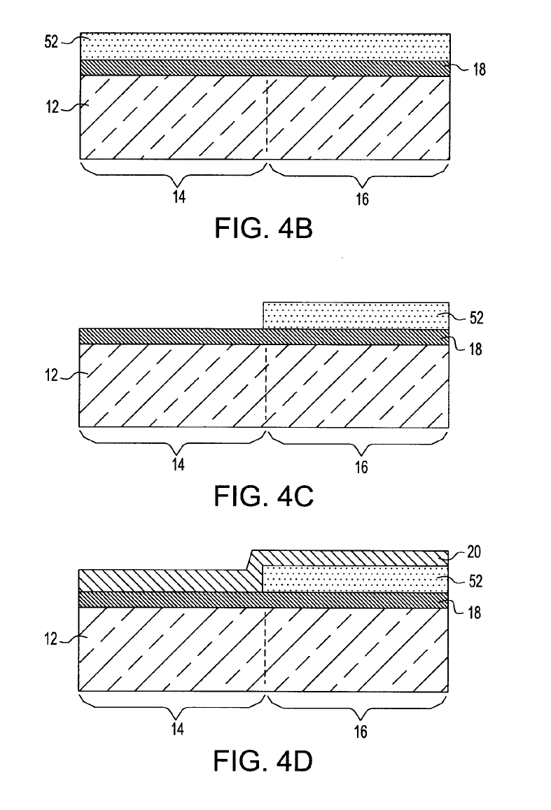

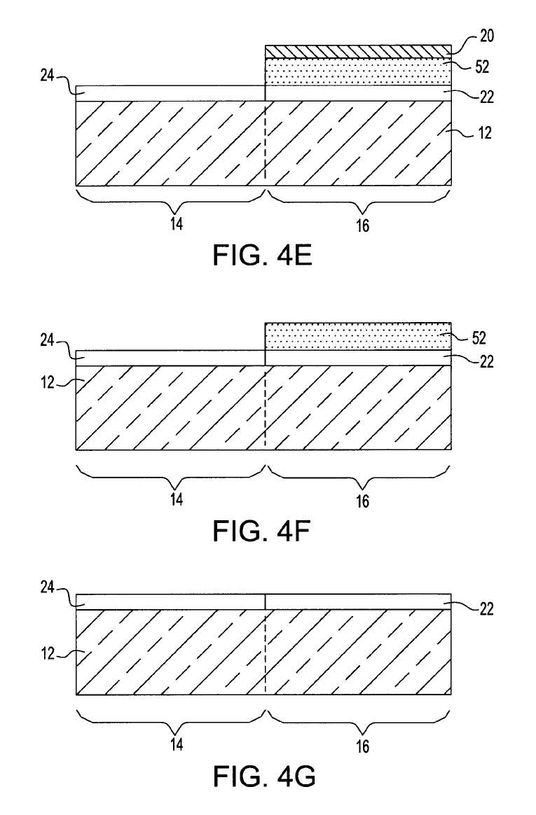

FIGS. 4A-4G are pictorial representations depicting a preferred embodiment of the present invention in which a single formation scheme is utilized in forming the regions of compositionally different suicides or germanides. In these drawings, like elements and/or components as employed above are referred to by like reference numerals. It is noted that the drawings provided for the preferred embodiment show more details of the processing steps of the present invention. These details are applicable to the various embodiments described above. Also, although Pt is used as the first metal 18, and Ni or NiPt is used for the second metal 20, other metals or alloys thereof as described above are applicable.

FIG. 4A shows an initial structure 70 that is employed in this preferred embodiment of the present invention. The initial structure 70 includes a Si-containing or Ge layer 12 that has a first region 14 and a second region 16. The first region 14 is an area in which nFETs will be subsequently formed and the second region 16 is an area in which pFETs will be subsequently formed. Although not shown, the Si-containing or Ge layer 12 includes device isolation regions therein which separates the two regions from each other. The device isolation regions may include trench isolation regions or field oxide isolation regions which are fabricated utilizing techniques that are well known in the art.

The initial structure 70 also includes a blanket layer of Pt as the first metal 18. The blanket layer of Pt is typically formed by sputtering or another physical deposition technique and it typically has a thickness from about 3 to about 30, preferably about 10 to about 20, nm.

FIG. 4B shows the structure after forming a hard mask 52 on the structure. Although any of the hard mask materials mentioned above can be used, it is preferred that a nitride material by used. The hard mask 52 is formed utilizing any of the techniques described above, with PECVD (at a temperature of less than 300° C.) being particularly preferred. The hard mask 52 typically has a thickness that is within the range from about 5 to about 50 nm.

Next, a patterned photoresist (not shown) is formed by deposition and lithography so as to protect either the first region 14 or the second region 16. In the specific embodiment shown, the patterned photoresist protects the material layers within the second region 16. The exposed hard mask 52 in the first region 14 is then selectively etched and the patterned photoresist is stripped. When nitride is used as the hard mask 52 a reactive ion etch step with oxygen and hydrocarbon radicals such as CH₃F can be used. Other etching processes as described above can also be used to selectively remove the exposed portion of the hard mask 52. The resultant structure including the patterned hard mask 52 is shown in FIG. 4C.

FIG. 4D shows the structure after forming a second metal 20 over the entire structure shown in FIG. 4C. In a preferred embodiment, the second metal 20 comprises Ni or a NiPt alloy. Sputtering or another physical deposition technique can be used. The Ni or NiPt alloy should have a thickness from about 3 to about 30 nm, with a thickness from about 10 to about 20 nm being more preferred.

Next, the structure provided in FIG. 4D is subjected to a single self-aligned silicidation process which forms to different suicides or germanides simultaneously. That is, a single self-aligned silicidation process is used in forming a first silicide or germanide 22 and a second silicide or germanide 24 which are compositionally different from each other. For this specific embodiment where Pt and Ni or NiPt are used, the annealing is performed at a temperature from about 350° to about 500° C. for a time period from about 30 seconds to about 30 minutes in nitrogen or argon. The anneal can be in a single step or in multiple steps.

In this step, Ni diffuses across the Pt layer in the first region 14 to form Ni silicide (or germanide) or NiPt silicide (or germanide) 24, while Pt silicide (or germanide) 22 forms in the second region 16. The resultant structure formed after performing the single self-aligned silicidation step is shown in FIG. 4E.

FIG. 4F shows the structure after etching any unreacted metal from the structure. This etching step utilizes a wet chemical etchant such as, for example, aqua regia. Note that the structure still includes the patterned hard mask 52 in the second region 16 atop the second silicide or germanide 24. The remaining hard mask 52 is then etched using a reactive ion etching process. A second etch in H₂SO₄:H₂O₂ or aqua regia can be used to remove any remaining metal that may be present, especially atop the first silicide or germanide 22. The resultant structure is shown, for example, in FIG. 4G.

It is noted that although the embodiments described above use a layer 12 that is comprised of either a Si-containing material or Ge in both regions 12 and 14, the present invention also contemplates instances wherein regions 12 and 14 are comprised of different materials. That is, region 12 can include, for example, a Si-containing material, while region 14 can include, for example, Ge. Likewise, region 12 may be composed of Ge, while region 14 may be composed of a Si-containing material.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of fabricating a semiconductor structure comprising: providing a Si-containing or Ge layer having at least a first region and a second region; forming a first silicide or germanide on one of said first or second regions; and forming a second silicide or germanide that is compositionally different from said first silicide or germanide on said other region not including said first silicide or germanide, wherein said steps of forming said first and second suicides or germanides are performed sequentially or in a single step.

2. The method of claim 1 wherein a Si-containing layer is provided and said Si-containing layer is selected from the group consisting of Si, SiGe, SiGeC, SiC, silicon-on-insulators and silicon germanium-on-insulators.

3. The method of claim 1 wherein each of said first and second regions includes a diffusion region.

4. The method of claim 1 wherein said first silicide or germanide is composed of a metal or metal alloy selected from the group consisting of Ti, Ta, W, Co, Ni, Pt, Pd and alloys thereof.

5. The method of claim 4 wherein said first silicide or germanide further comprises at least one alloying additive.

6. The method of claim 5 wherein said at least one alloying additive is selected from the group consisting of C, Al, Ti, V, Cr, Mn, Fe, Co, Ni, Cu, Ge, Zr, Nb, Mo, Ru, Rh, Ag, In, Hf, Ta, W, Re, Ir and Pt, with the proviso that the one or more alloying additive is different from said metal or metal alloy.

7. The method of claim 1 wherein said second silicide or germanide is composed of a metal or metal alloy selected from the group consisting of Ti, Ta, W, Co, Ni, Pt, Pd and alloys thereof.

8. The method of claim 7 wherein said first suicide or germanide further comprises at least one alloying additive.

9. The method of claim 8 wherein said at least one alloying additive is selected from the group consisting of C, Al, Ti, V, Cr, Mn, Fe, Co, Ni, Cu, Ge, Zr, Nb, Mo, Ru, Rh, Ag, In, Hf, Ta, W, Re, Ir and Pt, with the proviso that the one or more alloying additive is different from said metal or metal alloy.

10. The method of claim 1 wherein said steps of forming are performed in a single step utilizing a single self-aligned silicidation process.

11. The method of claim 10 wherein said single self-aligned silicidation process comprises a first anneal, removing any unreacted metal or metal alloy not converted to said silicide or germanide, and optionally a second anneal.

12. The method of claim 1 wherein said steps of forming are performed sequentially utilizing a first self-aligned silicidation process and a second self-aligned silicidation process.

13. A method of forming a semiconductor structure comprising:
providing a Si-containing or Ge layer having at least a first region and a second region;
forming a patterned first metal or metal alloy on one of said first or second regions;
forming a second metal or metal alloy that is compositionally different from said first metal or metal alloy within both of said regions; and
performing a single self-aligned silicidation process in which a first silicide or germanide is formed within one of said regions and a second silicide or germanide that is compositionally different from the first silicide or germanide is formed in the other region not including said first silicide or germanide.

14. The method of claim 13 wherein during said self-aligned silicidation process diffusion of the second metal or metal alloy into the first metal or metal alloy occurs forming a silicide or germanide including both said first and second metals or metal alloys.

15. The method of claim 13 wherein a patterned hard mask is formed in one of said regions including said first metal or metal alloy.

16. The method of claim 13 wherein said first and second metals or metal alloys are selected from the group consisting of Ti, Ta, W, Co, Ni, Pt, Pd and alloys thereof.

17. The method of claim 16 wherein said first and second metals or metal alloys further comprises at least one alloying additive selected from the group consisting of C, Al, Ti, V, Cr, Mn, Fe, Co, Ni, Cu, Ge, Zr, Nb, Mo, Ru, Rh, Ag, In, Hf, Ta, W, Re, Ir and Pt, with the proviso that the one or more alloying additive is different from said metal or metal alloy.

18. A method of fabricating a semiconductor structure comprising:
providing a Si-containing or Ge layer having at least a first region and a second region;
forming a first silicide or germanide on one of said first or second regions; and
forming a second silicide or germanide that is compositionally different from said first silicide or germanide on said other region not including said first silicide or germanide,
wherein said steps of forming said first and second suicides or germanides are performed sequentially.

19. The method of claim 18 wherein said first silicide or germanide is formed by providing a patterned hard mask to one of said regions, depositing a first metal or metal alloy atop said patterned hard mask and atop an exposed surface of said Si-containing or Ge layer, and performing a first self-aligned silicidation process.

20. The method of claim 19 wherein said second silicide or germanide is formed by removing said patterned hard mask, depositing a second metal or metal ally atop the Si-containing and Ge layer, and performing a second self-aligned silicidation process.
